(19) United States
(12) Patent Application Publication
(10) Pub. No.: US 2009/0278160 A1
(43) Pub. Date: Nov. 12, 2009

(54) RADIATION EMITTING SEMICONDUCTOR DEVICE

(75) Inventors: WEN YU LIN, TAICHUNG COUNTY (TW); SHIH CHENG HUANG, HSINCHU CITY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/435,984

(22) Filed: May 5, 2009

(30) Foreign Application Priority Data
May 9, 2008 (TW) 097117098

(51) Int. Cl. H01L 33/00; H01L 21/283; H01S 5/323

(52) U.S. Cl. 257/99; 438/46; 372/43.01; 257/E33.062; 257/E21.159

(57) ABSTRACT

The present invention provides a radiation emitting semiconductor device, which comprises an active layer for emitting radiation, a p-type conductive layer, a transparent conductive layer, and a non-p-type ohmic contact layer. The p-type conductive layer is formed on the active layer. The transparent conductive layer is formed on the p-type conductive layer. The non-p-type ohmic contact layer is disposed between said p-type conductive layer and said transparent conductive layer. The non-p-type ohmic contact layer is configured to reduce the operating voltage of said radiation emitting semiconductor device. In addition, the present invention provides that the non-p-type ohmic contact layer is made of a quaternary alloy of AlₓIn_{y}Ga_{1-x-y}N. The aluminum composition in the quaternary alloy of AlₓIn_{y}Ga_{1-x-y}N can be used to adjust the band gap energy of the quaternary alloy such that the band gap energy of the quaternary alloy is larger than that of the active layer, thereby reducing the absorption of radiation by the non-p-type ohmic contact layer.

### BACKGROUND OF THE INVENTION

1. Field of the Invention

The present invention relates to a radiation emitting semiconductor device, and relates more particularly to a radiation emitting semiconductor device having a low operating voltage.

2. Description of the Related Art

Light emitting diode (LED) devices, made of semiconductor material, are micro-scale solid-state light sources that transform electrical energy to radiant energy. Because LED devices have many advantages such as small configuration, longer life, low operating voltage, low heat dissipation, low electrical consumption, high speed response, lack of mercury pollution, single color emission, and can be used with various apparatuses having light, thin and miniaturized requirements, LEDs have become widely applied in consumer electronic devices.

To date, most development attention has been directed toward the LED devices using Group-III nitride semiconductor materials such as gallium nitride (GaN), aluminum nitride (AlN), aluminum gallium nitride (AlGaN), indium gallium nitride (InGaN), aluminum indium gallium nitride (AlInGaN).

In the semiconductor devices using Group-III nitride semiconductor materials, the p-type conductive layer is made of p-type GaN, which is a p-type doped Group-III material. Because the doping concentration of a p-type nitride semiconductor cannot be as high as that of an n-type semiconductor, a p-electrode and a p-type semiconductor cannot achieve good ohmic contact. Therefore, a transparent conductive metal oxide layer has to be formed on the p-type conductive layer such that a planar contact is formed to reduce contact resistance.

The transparent conductive metal oxide materials such as indium tin oxide (ITO) and nickel oxide (NiO) are widely used in optoelectronic devices, for example thin-film transistor liquid crystal displays (TFT-LCD), organic light-emitting devices (OLED) and light emitting diodes. Specifically, in the LED devices based on Group-III semiconductor materials, it is more common to use the transparent conductive metal oxide materials. The transparent conductive metal oxide materials used in optoelectronic devices acts as an electron conductive layer and a light transmission layer. Current optoelectronic device technology needs an improved technique that would allow optoelectronic devices to have lower and more stable forward operating voltages. However, it is not easy to form an ohmic contact layer between ITO and p-type GaN layers.

Generally, the solution for lower contact resistance adopted by the conventional method is to form a high concentration p-type contact layer. However, the high concentration p-type contact layer may absorb electromagnetic radiation due to the band gap of dopants, and the high concentration of the dopants may cause carriers to diffuse, leading to instability in operating voltage.

Therefore, a new structure of a light emitting diode shall be developed to lower operating voltage, increase light extraction efficiency and increase light emission intensity, thereby meeting current market requirements.

### SUMMARY OF THE INVENTION

The present invention provides a non-p-type ohmic contact layer, which is configured to reduce the operating voltage of a radiation emitting semiconductor device.

The present invention provides a non-p-type ohmic contact layer, which includes no magnesium, thereby reducing the light absorption.

The present invention provides a non-p-type ohmic contact layer, made of quaternary alloy of AlₓIn_{y}Ga_{1-x-y}N, a monocrystal epitaxial layer, which can achieve stable conductive characteristics and can avoid multiple reflections incurred by multiple surfaces.

The present invention provides a radiation emitting semiconductor device, which comprises an active layer, a p-type conductive layer, a transparent conductive layer, and a non-p-type ohmic contact layer. The p-type conductive layer is formed on the active layer. The transparent conductive layer is formed on the p-type conductive layer. The non-p-type ohmic contact layer is disposed between the p-type conductive layer and the transparent conductive layer.

### BRIEF DESCRIPTION OF THE DRAWINGS

The invention will be described according to the appended drawings in which:

FIG. 1 shows a cross sectional view of a radiation emitting semiconductor device of the present invention; and

FIG. 2 is a graph showing current-voltage relationships for a radiation emitting semiconductor device and a conventional light emitting diode.

### DETAILED DESCRIPTION OF THE INVENTION

The present invention provides a radiation emitting semiconductor device. For complete understanding of the present invention, the following description will describe in detail the method steps and the components. The present invention is not limited by the specified particulars of the radiation emitting semiconductor devices that are familiar to persons skilled in the art. In addition, well-known components or method steps are not described in detail so as to avoid any additional limitation. The preferable embodiments of the present invention are described in detail. In addition to the detailed descriptions, the present invention also can be applied to other embodiments. Therefore, the scope of the present invention is not limited, and is dependent on the following claims.

In semiconductor devices based on GaN, AlGaN, and InGaN, the material of the p-type conductive layer is a p-type GaN material. However, because the contact interface between the p-type conductive layer and a p-electrode layer such as a transparent conductive layer or metal exhibits higher contact resistance, the higher contact resistance converts electrical energy into heat dissipation such that the operation of the device is influenced. With GaN-based semiconductor devices, the power consumption of the contact resistance occupies 50% or more of the total power of the semiconductor device. Moreover, the dissipated heat may increase the temperature of the device, and high temperature may damage the device. Therefore, the contact resistance has to be minimized as much as possible. Furthermore, in GaN-based semiconductor devices, the contact resistance between an n-type conductive layer and the film connected to the n-type conductive layer is much smaller than that between a p-type conductive layer and the film connected to the p-type conductive layer. However, the total power consumption in a semiconductor device is the power consumed by the total contact resistance in series. Hence, it is necessary to reduce the contact resistance between a p-type conductive layer and the film connected to the p-type conductive layer so as to reduce the total contact resistance in series. Hereinafter, four prior art methods are described that attempt to solve the above-mentioned problem.

U.S. Pat. No. 7,105,850 discloses a structure with a p-type contacting layer grown upon a p-type cladding layer, which is on an active layer. The material of the p-type contact layer is Al—Mg codoped indium gallium nitride (In_{1-y}Ga_{y}N). The structure can reduce operating voltage. However, because the material of the p-type contact layer suggested in this invention includes magnesium, the structure may have lower light extraction efficiency due to the band gap of magnesium.

U.S. Pat. No. 7,005,681 discloses a magnesium-doped or zinc-doped indium gallium nitride which can be used as the material of the p-type contact layer for reducing contact resistance. The p-type contact layer of a semiconductor device based on the indium gallium nitride of this invention may have 0.08 amperes output current when the operating voltage reaches 6 volts. Compared to conventional semiconductor devices with p-GaN contact layer, the operating voltage of the indium gallium-nitride semiconductor device is lower, but the operating voltage of 6 volts is still too high. Moreover, similar to the above-mentioned U.S. Pat. No. 7,105,850, the contact layer is built with magnesium-doped metal, and the device may have lower light extraction efficiency due to the band gap of magnesium.

U.S. Pat. No. 7,132,695 proposes a light emitting diode having a dual dopant contact layer, which is doped by a p-type impurity and an n-type impurity simultaneously and can lower contact resistance. The proposed p-type impurity is magnesium (Mg), zinc (Zn), beryllium (Be) and calcium (Ca); and the n-type impurity is silicon (Si), germanium (Ge), tin (Sn), tellurium (Te), oxygen, and carbon. The conductive characteristic of this dual dopant contact layer is not easy to control and the stability thereof is not easily assured.

U.S. Pat. No. 6,995,403 discloses a light emitting device with a contact layer that has a stacked structure formed by alternately stacking a plurality of nitride semiconductor layers having a wider bandgap and a plurality of nitride semiconductor layers having a narrower bandgap. The stacked structure is used as a contact layer between a transparent conductive layer and a p-type contact layer to lower contact resistance. However, due to the effect of Fresnel loss, when radiation passes through the interface between two media, multiple reflections may occur at the interface and cause the loss of photon energy. Therefore, additional interfaces may cause more reflections such that photons may be blocked from emitting out of the semiconductor device.

To summarize the issues of the above-mentioned patent, a magnesium-doped contact layer may have lower light extraction efficiency; the conductive characteristic of the dual dopant contact layer, which is simultaneously doped by a p-type impurity and an n-type impurity, is not easy to control and the stability thereof is not easily assured; and a light emitting device with a contact layer that has a stacked structure may cause photon energy loss. The present invention provides a solution that can lower the contact resistance and avoid the above-mentioned drawbacks.

The present invention mainly proposes a method that uses epitaxial process to grow a non-p-type doping ohmic contact layer contacted with a transparent conductive layer (TCL) to lower the operating voltage of an LED, to reduce the heat generated by the resistance between p-type conductive layer and the transparent conductive layer, and to minimize the influence of joule heating on quantum wells. As such, the total lighting efficiency and wall plug efficiency of the LED can be improved. The wall plug efficiency is related to device characteristics such as the bandgap of material, defects, impurities and the epitaxial constitution and structure of the device. Simultaneously, the non-p-type doping ohmic contact layer does not include magnesium, and accordingly has a lower rate of light absorption. Furthermore, the non-p-type doping ohmic contact layer of the present invention is suitable for use with many types of transparent conductive layers, for example indium tin oxide, indium zinc oxide, zinc oxide, nickel oxide, cadmium tin oxide or a mixture thereof, and ZnO:Al, ZnGa₂O₄, SnO₂:Sb, Ga₂O₃:Sn, AgInO₂:Sn, In₂O₃:Zn, CuAlO₂, LaCuOS, CuGaO₂ or SrCu₂O₂ or mixture thereof.

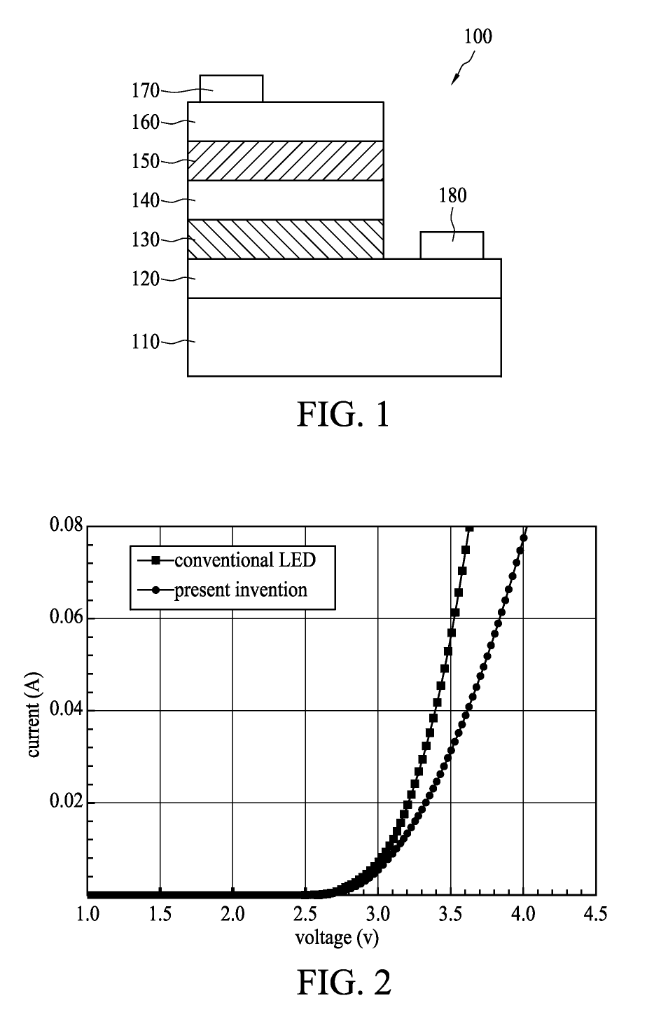

FIG. 1 shows a cross sectional view of a radiation emitting semiconductor device 100 of the present invention, wherein the layers built upon a substrate 110 comprise an n-type conductive layer 120, an active layer 130 configured to produce radiation, a p-type conductive layer 140, a non-p-type ohmic contact layer 150, a transparent conductive layer 160, a p-electrode layer 170, and an n-electrode layer 180 contacting the n-type conductive layer 120. The n-type conductive layer 120 is disposed on the surface of the substrate 110; the active layer 130 is upon the n-type conductive layer 120; the p-type conductive layer 140 is upon the active layer 130; the transparent conductive layer 160 is formed on the p-type conductive layer 140, the non-p-type ohmic contact layer 150 is between the p-type conductive layer 140 and the transparent conductive layer 160.

The above-described radiation emitting semiconductor device 100 can be a light emitting diode or a laser diode, and the substrate 110 may include C-Plane, R-Plane, A-Plane mono-crystals of aluminum oxide (sapphire), and silicon carbide (6H—SiC or 4H—SiC), or may be Si, ZnO, GaAs, MgAl₂O₄, or mono-crystal oxides with lattice constant close to those of Group-III semiconductor materials. In addition, the n-type conductive layer 120, the active layer 130, and the p-type conductive layer 140 are made of Group-III semiconductor material. The material of the p-electrode layer 170 is from the group of: nickel, palladium, platinum, chromium, gold, titanium, silver, aluminum, germanium, tungsten, tungsten silicide, tantalum, gold zinc (AuZn), gold-beryllium (AuBe), gold-germanium (Au—Ge) and gold germanium nickel (AuGeNi).

The non-p-type ohmic contact layer 150 proposed by the present invention is quaternary alloy of AlₓIn_{y}Ga_{1-x-y}N. The AlₓIn_{y}Ga_{1-x-y}N layer is a monocrystal epitaxial layer. The non-p-type ohmic contact layer 150 is configured for lowering the operating voltage of the radiation emitting semiconductor device 100. The ranges of x and y in the AlₓIn_{y}Ga_{1-x-y}N are 0≦x≦1 and 0≦y≦1 respectively. The thickness of the non-p-type ohmic contact layer is between about 10 Å and 1000 Å. The non-p-type ohmic contact layer 150 based on AlₓIn_{y}Ga_{1-x-y}N can achieve stable conductive characteristics, and the epitaxially grown monocrystalline structure thereof can avoid multiple reflections incurred by multiple surfaces. Moreover, the aluminum composition in quaternary alloy of AlₓIn_{y}Ga_{1-x-y}N can be used to adjust the band gap energy of the quaternary alloy such that the band gap energy of the quaternary alloy can be adjusted to be larger than that of the active layer and thereby reduce light absorption by the non-p-type ohmic contact layer 150.

FIG. 2 is a graph showing current-voltage relationships for a radiation emitting semiconductor device (a light emitting diode) and a conventional light emitting diode. In FIG. 2, the round dot curve and the square dot curve represent the radiation emitting semiconductor device of the present invention and the conventional light emitting diode, respectively. The graph clearly shows that to obtain a current of 0.08 amperes, the radiation emitting semiconductor device of the present invention (square dot curve) needs only 3.6 volts, while to obtain the same current (0.08 amperes) the conventional light emitting diode (round dot curve) needs 4.0 volts. Therefore, the radiation emitting semiconductor device of the present invention can actually reduce the required operating voltage.

The present invention provides a method for reducing operating voltage of a radiation emitting semiconductor device, the method comprising the steps of: providing a substrate; forming an n-type conductive layer, an active layer for emitting radiation, and a p-type conductive layer; forming a non-p-type ohmic contact layer and a transparent conductive layer (TCL) sequentially on said p-type conductive layer; and finally forming a p-electrode layer and an n-electrode layer on the transparent conductive layer and the n-type conductive layer respectively, wherein the non-p-type ohmic contact layer is used for reducing operating voltage of the radiation emitting semiconductor device.

The radiation emitting semiconductor device of the present invention can be a light emitting diode or a laser diode. The non-p-type ohmic contact layer proposed by the present invention is a quaternary alloy of AlₓIn_{y}Ga_{1-x-y}N, and the AlₓIn_{y}Ga_{1-x-y}N layer is a monocrystal epitaxial layer. The ranges of x and y in the AlₓIn_{y}Ga_{1-x-y}N are 0≦x≦1 and 0≦y≦1 respectively. The thickness of the non-p-type ohmic contact layer is between about 10 Å and 1000 Å.

In addition, the substrate used in the method of the present invention may include C-Plane, R-Plane, A-Plane mono-crystals of aluminum oxide (sapphire), and silicon carbide (6H—SiC or 4H—SiC), or may be Si, ZnO, GaAs, MgAl₂O₄, or mono-crystal oxides with lattice constant close to those of Group-III semiconductor materials. The n-type conductive layer 120, the active layer 130, and the p-type conductive layer 140 are made of Group-III semiconductor material.

The above-described embodiments of the present invention are intended to be illustrative only. Numerous alternative embodiments may be devised by persons skilled in the art without departing from the scope of the following claims.

What is claimed is:

1. A radiation emitting semiconductor device, comprising:
an active layer for emitting radiation;
a p-type conductive layer disposed on said active layer;
a transparent conductive layer (TCL) disposed on said p-type conductive layer; and
a non-p-type ohmic contact layer disposed between said p-type conductive layer and said transparent conductive layer.

2. The radiation emitting semiconductor device as in claim 1, wherein said semiconductor device is a light emitting diode (LED).

3. The radiation emitting semiconductor device as in claim 1, wherein said semiconductor device is a laser diode (LD).

4. The radiation emitting semiconductor device as in claim 1, wherein said non-p-type ohmic contact layer is a quaternary alloy of AlₓIn_{y}Ga_{1-x-y}N with 0≦x≦1, 0≦y≦1 and the band gap of said non-p-type ohmic contact layer is larger than the band gap of said active layer, thereby reducing light absorption by said non-p-type ohmic contact layer.

5. The radiation emitting semiconductor device as in claim 1, wherein the thickness of said non-p-type ohmic contact layer ranges from 10 Å to 1000 Å.

6. The radiation emitting semiconductor device as in claim 1, wherein said non-p-type ohmic contact layer is used for reducing operating voltage of said radiation emitting semiconductor device.

7. The radiation emitting semiconductor device as in claim 1, wherein said non-p-type ohmic contact layer is a monocrystal epitaxial layer.

8. The radiation emitting semiconductor device as in claim 1, further comprising a substrate and an n-type conductive layer, wherein said n-type conductive layer is disposed between said substrate and said active layer.

9. The radiation emitting semiconductor device as in claim 8, wherein said substrate is Al₂O₃ or SiC.

10. The radiation emitting semiconductor device as in claim 1, wherein said transparent conductive layer is indium tin oxide (ITO), indium zinc oxide (IZO), zinc oxide (ZnO), nickel oxide (NiO), cadmium tin oxide (CTO), ZnO:Al, ZnGa₂O₄, SnO₂:Sb, Ga₂O₃:Sn, AgInO₂:Sn, In₂O₃:Zn, CuAlO₂, LaCuOS, CuGaO₂, or SrCu₂O₂ or a mixture thereof.

11. A method for reducing operating voltage of a radiation emitting semiconductor device, comprising:
providing a substrate;
forming an n-type conductive layer, an active layer for emitting radiation, and a p-type conductive layer sequentially on said substrate;
forming a non-p-type ohmic contact layer and a transparent conductive layer (TCL) sequentially on said p-type conductive layer, wherein said non-p-type ohmic contact layer is used for reducing operating voltage of said radiation emitting semiconductor device.

12. The method for reducing operating voltage of a radiation emitting semiconductor device as in claim 11, wherein said radiation emitting semiconductor device is a light emitting diode (LED) or laser diode (LD).

13. The method for reducing operating voltage of a radiation emitting semiconductor device as in claim 11, wherein said non-p-type ohmic contact layer is a quaternary alloy of AlₓIn_{y}Ga_{1-x-y}N with 0≦x≦1, 0≦y≦1, and the band gap of said non-p-type ohmic contact layer is larger than the band gap of said active layer, thereby reducing light absorption by said non-p-type ohmic contact layer.

14. The method for reducing operating voltage of a radiation emitting semiconductor device as in claim 11, wherein the thickness of said non-p-type ohmic contact layer ranges from 10 Å to 1000 Å.

15. The method for reducing operating voltage of a radiation emitting semiconductor device as in claim 11, wherein said non-p-type ohmic contact layer is a monocrystal epitaxial layer.

16. The method for reducing operating voltage of a radiation emitting semiconductor device as in claim 11, wherein said transparent conductive layer is indium tin oxide (ITO), indium zinc oxide (IZO), zinc oxide (ZnO), nickel oxide (NiO), cadmium tin oxide (CTO), ZnO:Al, ZnGa₂O₄, SnO₂:Sb, Ga₂O₃:Sn, AgInO₂:Sn, In₂O₃:Zn, CuAlO₂, LaCuOS, CuGaO₂ or SrCu₂O₂ or a mixture thereof.
